(19) United States
(12) Patent Application Publication
(10) Pub. No.: US 2026/0026217 A1
(43) Pub. Date: Jan. 22, 2026

(54) Array Substrate, Display Panel and Display Apparatus

(71) Applicants: CHENGDU BOE OPTOELECTRONICS TECHNOLOGY, Chengdu, Sichuan (CN); BOE TECHNOLOGY GROUP CO., LTD, Chaoyang District, Beijing (CN)

(72) Inventors: Yuanjie Xu, Beijing (CN); Taofeng Xie, Beijing (CN); Mingzhi Chai, Beijing (CN); Meng Li, Beijing (CN); Xingliang Xiao, Beijing (CN); Zhuoan Li, Beijing (CN)

(21) Appl. No.: 18/864,752

(22) PCT Filed: Feb. 19, 2024
(86) PCT No.: PCT/CN2024/077575

§ 371 Date: Nov. 11, 2024

(51) Int. Cl. H10K 59/131

(52) U.S. Cl. CPC H10K 59/131

(57) ABSTRACT

An array substrate includes pixel circuits, first data lines, first connection lines and second connection lines. The pixel circuits each include a capacitor, a first reset transistor and a compensation transistor. Ends of a first connection line are connected to a second electrode plate of the capacitor and a second electrode of the compensation transistor. The first connection line is located between two adjacent first data lines and is closer to a first data line. Ends of a second connection line are connected to a second electrode of the first reset transistor and a first electrode of the compensation transistor. In a second direction, the second connection line is located on a side of the first connection line away from the closer first data line. A maximum distance between the first connection line and the second connection line is less than or equal to 2.4 μm.

### CROSS-REFERENCE TO RELATED APPLICATION

This application is the United States national phase of International Patent Application No. PCT/CN2024/077575, filed Feb. 19, 2024, the disclosure of which is hereby incorporated by reference in its entirety.

### BACKGROUND OF THE INVENTION

### Field of the Invention

The present disclosure relates to the field of display technologies, and in particular, to an array substrate, a display panel and a display apparatus.

### Description of Related Art

With the rapid development of display technologies, display apparatuses have gradually come throughout people's lives. Due to self-luminescence, low power consumption, wide viewing angle, fast response speed, high contrast, flexible display and other advantages, organic light-emitting diodes (OLEDs) are widely used in smart products such as a mobile phone, a television and a notebook computer.

### SUMMARY OF THE INVENTION

In an aspect, an array substrate is provided. The array substrate includes pixel circuits, a plurality of first data lines, a plurality of first connection lines and a plurality of second connection lines. The pixel circuits each include a capacitor, a first reset transistor and a compensation transistor. A first electrode plate of the capacitor is connected to a first voltage signal terminal, and a second electrode plate of the capacitor is connected to a first node. A first electrode of the first reset transistor is connected to a first initial signal terminal, and a second electrode of the first reset transistor is connected to a second node. A first electrode of the compensation transistor is connected to the second node, and a second electrode of the compensation transistor is connected to the first node.

The first data lines extend in a first direction. The plurality of first data lines are arranged at intervals in a second direction. The second direction intersects the first direction. A first data line is connected to a pixel circuit. The first connection lines extend in the first direction. An end of a first connection line is connected to the second electrode plate of the capacitor, and another end of the first connection line is connected to the second electrode of the compensation transistor. The first connection line is located between two adjacent first data lines, and is closer to a first data line of the two first data lines.

The second connection lines extend in the first direction. An end of a second connection line is connected to the second electrode of the first reset transistor, and another end of the second connection line is connected to the first electrode of the compensation transistor. The second connection line is located between the two adjacent first data lines. In the second direction, the second connection line is located on a side of the first connection line away from the first data line to which the first connection line is closer. In the second direction, a maximum distance between the first connection line and the second connection line that are adjacent is less than or equal to 2.4 μm.

In some embodiments, the plurality of first data lines each include straight segments and bent segments that are alternately connected. The plurality of first data lines are divided into a plurality of data line groups. Each data line group includes two first data lines. Bent segments of two first data lines in a same data line group are disposed oppositely and bent toward directions away from each other. The first connection line and the second connection line are located between two first data lines that belong to different data line groups and are adjacent. In the second direction, the first connection line is at least partially opposite to a bent segment, and opposite edges of a portion of the first connection line opposite to the bent segment and an adjacent second connection line are parallel.

In some embodiments, the first connection line includes a first connection pad, a first routing segment, a second routing segment and a second connection pad that are connected in sequence. The first connection pad is connected to the second electrode plate of the capacitor, and the second connection pad is connected to the second electrode of the compensation transistor. The second connection line includes a third connection pad, a third routing segment, a fourth routing segment and a fourth connection pad that are connected in sequence. The third connection pad is connected to the first electrode of the compensation transistor, and the fourth connection pad is connected to the second electrode of the first reset transistor.

In a direction from the first connection pad to the second connection pad, the first routing segment extends toward a direction close to the adjacent second connection line, and is located on a side of the third routing segment away from the fourth connection pad. In the second direction, the first routing segment is opposite to the third connection pad, the second routing segment is opposite to the third routing segment, and the fourth routing segment is opposite to the second connection pad. Opposite edges of the second routing segment and the third routing segment are parallel, and opposite edges of the second connection pad and the fourth routing segment are parallel.

In some embodiments, in the second direction, the fourth routing segment is opposite to a portion of the second connection pad, and the fourth connection pad is opposite to another portion of the second connection pad. Orthographic projections of the second connection pad and the fourth connection pad on a reference plane are each in a shape of a polygon, and opposite edges of the second connection pad and the fourth connection pad are parallel. The reference plane is a plane determined by the first direction and the second direction.

In some embodiments, the second routing segment includes a first sub-segment, a second sub-segment and a third sub-segment that are connected in sequence. The first sub-segment is connected to the first routing segment, the third sub-segment is connected to the second connection pad, and the third sub-segment is farther away from the closer first data line than the first sub-segment. The third routing segment includes a fourth sub-segment, a fifth sub-segment and a sixth sub-segment that are connected in sequence. The fourth sub-segment is connected to the third connection pad, the sixth sub-segment is connected to the fourth routing segment, and the sixth sub-segment is farther away from the closer first data line than the fourth sub-segment. In the second direction, the first sub-segment is opposite to the fourth sub-segment, the second sub-segment is opposite to the fifth sub-segment, and the third sub-segment is opposite to the sixth sub-segment.

In some embodiments, opposite edges of the first routing segment and the adjacent second connection line are at least partially parallel.

In some embodiments, an orthographic projection of an edge of the first connection line proximate to the first data line to which the first connection line is closer on a reference plane coincides with an orthographic projection of an edge of the second electrode of the compensation transistor, connected to the first connection line, proximate to a corresponding first data line on the reference plane. The reference plane is a plane determined by the first direction and the second direction.

In some embodiments, the pixel circuits each further include a driving transistor, a data writing transistor, a first enabling transistor, a second enabling transistor, a second reset transistor and a third reset transistor.

A control electrode of the driving transistor is connected to the first node, a first electrode of the driving transistor is connected to a third node, and a second electrode of the driving transistor is connected to the second node. A control electrode of the data writing transistor is connected to a second scanning signal terminal, a first electrode of the data writing transistor is connected to a data signal terminal, and a second electrode of the data writing transistor is connected to the third node. A control electrode of the first enabling transistor is connected to an enabling signal terminal, a first electrode of the first enabling transistor is connected to the first voltage signal terminal, and a second electrode of the first enabling transistor is connected to the third node.

A control electrode of the second enabling transistor is connected to the enabling signal terminal, a first electrode of the second enabling transistor is connected to the second node, and a second electrode of the second enabling transistor is connected to a fourth node. A control electrode of the second reset transistor is connected to a second reset signal terminal, a first electrode of the second reset transistor is connected to a second initial signal terminal, and a second electrode of the second reset transistor is connected to the fourth node. A control electrode of the third reset transistor is connected to the second reset signal terminal, a first electrode of the third reset transistor is connected to a third initial signal terminal, and a second electrode of the third reset transistor is connected to the third node.

In some embodiments, the array substrate includes a first active layer. The first active layer includes a plurality of first active patterns, a plurality of second active patterns and a plurality of third active patterns.

The first active patterns include a channel, a first electrode and a second electrode of the driving transistor, a channel, a first electrode and a second electrode of the data writing transistor, a channel, a first electrode and a second electrode of the first enabling transistor, a channel, a first electrode and a second electrode of the second enabling transistor, and a channel, a first electrode and a second electrode of the second reset transistor. The second active patterns include a channel, a first electrode and a second electrode of the first reset transistor. The plurality of first active patterns and the plurality of second active patterns are alternately arranged in the first direction, and a second active pattern is farther away from a corresponding first data line than a corresponding first active pattern. The third active patterns include a channel, a first electrode and a second electrode of the third reset transistor. In the second direction, a third active pattern is located on a side of the channel of the second reset transistor proximate to the channel of the first enabling transistor.

In some embodiments, the array substrate further includes first scanning signal lines, and the first scanning signal lines extend in the second direction. An orthographic projection of a first scanning signal line on a reference plane overlaps with an orthographic projection of a channel of the compensation transistor on the reference plane, and the reference plane is a plane determined by the first direction and the second direction. Orthographic projections of the first scanning signal line and the first connection line on the reference plane overlap, and an edge of an overlapping portion is parallel to the first direction or the second direction.

In some embodiments, the first scanning signal line includes a plurality of first scanning routing segments connected in sequence. A first scanning routing segment includes a first scanning sub-segment and a second scanning sub-segment connected in sequence. An orthographic projection of the first scanning sub-segment on the reference plane overlaps with the orthographic projection of the first connection line on the reference plane, and an orthographic projection of the second scanning sub-segment on the reference plane overlaps with the orthographic projection of the channel of the compensation transistor on the reference plane. In the first direction, a width of the first scanning sub-segment is smaller than a width of the second scanning sub-segment, and an edge connecting the second scanning sub-segment and the first scanning sub-segment is parallel to an opposite edge of the first connection line.

In some embodiments, the first scanning signal line includes a plurality of first scanning routing segments connected in sequence. A first scanning routing segment includes a third scanning sub-segment, a fourth scanning sub-segment and a fifth scanning sub-segment connected in sequence. An orthographic projection of the fourth scanning sub-segment on the reference plane overlaps with the orthographic projection of the first connection line on the reference plane, and an orthographic projection of the fifth scanning sub-segment on the reference plane overlaps with the orthographic projection of the channel of the compensation transistor on the reference plane. In the first direction, a width of the third scanning sub-segment is smaller than a width of the fourth scanning sub-segment, and the width of the fourth scanning sub-segment is smaller than a width of the fifth scanning sub-segment.

In some embodiments, an edge connecting the fourth scanning sub-segment and the third scanning sub-segment is parallel to an opposite edge of the first connection line. And/or an edge connecting the fifth scanning sub-segment and the fourth scanning sub-segment is parallel to the opposite edge of the first connection line.

In some embodiments, the array substrate includes a second active layer, a second gate conductive layer and a third gate conductive layer. The second active layer includes a plurality of fourth active patterns, and a fourth active pattern includes a channel, a first electrode and a second electrode of the compensation transistor. The second gate conductive layer and the third gate conductive layer are disposed on opposite sides of the second active layer. The first scanning signal lines are located in the second gate conductive layer and/or the third gate conductive layer.

In some embodiments, the pixel circuits each further include a driving transistor and a data writing transistor. A first electrode of the driving transistor is connected to a third node, and a second electrode of the driving transistor is connected to the second node. A first electrode of the data writing transistor is connected to the first data line, and a second electrode of the data writing transistor is connected to the third node.

The array substrate further includes a second scanning signal line. The second scanning signal line extends in the second direction. An orthographic projection of the second scanning signal line on a reference plane overlaps with an orthographic projection of a channel of the data writing transistor on the reference plane, and overlaps with an orthographic projection of the second electrode of the compensation transistor on the reference plane. The reference plane is a plane determined by the first direction and the second direction.

The second scanning signal line includes a second scanning routing segment and widened portions. In the first direction, the widened portions are located on a side of the second scanning routing segment, and orthographic projections of the widened portions on the reference plane are located within the orthographic projection of the second electrode of the compensation transistor on the reference plane.

In some embodiments, the array substrate further includes a plurality of first power signal lines. An orthographic projection of the first connection line on a reference plane is located within an orthographic projection of the plurality of first power signal lines on the reference plane. The reference plane is a plane determined by the first direction and the second direction.

In some embodiments, the plurality of first power signal lines include a plurality of first power sub-lines, a plurality of second power sub-lines and a plurality of third power sub-lines. The plurality of first power sub-lines extend in the first direction and are arranged at intervals in the second direction. The plurality of second power sub-lines extend in the first direction and are arranged at intervals in the second direction. A second power sub-line is connected to a first voltage signal terminal of the pixel circuit. The plurality of third power sub-lines extend in the second direction and are arranged at intervals in the first direction. A first power sub-line is connected to a second power sub-line by a third power sub-line.

Part of the orthographic projection of the first connection line on the reference plane is located within an orthographic projection of the first power sub-line or the second power sub-line on the reference plane, and other part of the orthographic projection of the first connection line on the reference plane is located within an orthographic projection of the third power sub-line on the reference plane.

In some embodiments, the array substrate includes a first source-drain conductive layer, a second source-drain conductive layer and a third source-drain conductive layer. The first connection lines and the second connection lines are located in the first source-drain conductive layer. The third power sub-lines are located in the second source-drain conductive layer. The first power sub-lines and the second power sub-lines are located in the third source-drain conductive layer.

In another aspect, a display panel is provided. The display panel includes the array substrate as described in any of the above embodiments and light-emitting devices. The light-emitting devices are disposed on the array substrate.

In yet another aspect, a display apparatus is provided. The display apparatus includes the display panel as described in the above embodiment and a circuit board. The circuit board is connected to the display panel.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of another display apparatus, in accordance with some embodiments;

FIG. 3 is a sectional view of the display apparatus in FIG. 1 taken along a section line A-A;

FIG. 4 is a top view of a display panel, in accordance with some embodiments;

FIG. 5 is a sectional view of a display panel, in accordance with some embodiments;

FIG. 6 is a circuit diagram of a pixel circuit, in accordance with some embodiments;

FIG. 7 is a partial enlarged view of a first connection line and a second connection line in an array substrate, in accordance with some embodiments;

FIG. 8 is a partial enlarged view of a first connection line and a second connection line in another array substrate, in accordance with some embodiments;

FIG. 9 is a top view of a stack of a first source-drain conductive layer, a second source-drain conductive layer and a third source-drain conductive layer in an array substrate, in accordance with some embodiments;

FIG. 10 is a top view of a first source-drain conductive layer in an array substrate, in accordance with some embodiments;

FIG. 11 is a top view of a first active layer in an array substrate, in accordance with some embodiments;

FIG. 12 is a top view of a second source-drain conductive layer in an array substrate, in accordance with some embodiments;

FIG. 13 is a top view of a third source-drain conductive layer in an array substrate, in accordance with some embodiments;

FIG. 14 is a top view of a third source-drain conductive layer in another array substrate, in accordance with some embodiments;

FIG. 15 is a structural diagram of a first connection line and a second connection line in an array substrate, in accordance with some embodiments;

FIG. 16 is a structural diagram of a first connection line and a second connection line in another array substrate, in accordance with some embodiments;

FIG. 17 is a top view of a first gate conductive layer in an array substrate, in accordance with some embodiments;

FIG. 18 is a top view of a second active layer in an array substrate, in accordance with some embodiments;

FIG. 19 is a top view of a second gate conductive layer in an array substrate, in accordance with some embodiments; and

FIG. 20 is a top view of a third gate conductive layer in an array substrate, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “connected” and derivatives thereof may be used. The term “connection” should be understood in a broad sense. For example, the “connection” may be a mechanical connection or an electrical connection; it may be a fixed connection, a detachable connection, or of an integrated structure; it may be a direct connection, an indirect connection by an intermediate medium, or an internal communication between two elements. Specific meanings of the above terms in the article may be understood by a person of ordinary skill in the art depending on specific situations.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°, and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

The term “overlapping” or “overlapped” means that a first object may be located above or below a second object or to a side surface of a second object, and vice versa. In addition, the term “overlapping” may include piling, stacking, being opposite or facing, extending over, covering or partially covering, or any other suitable term that will be appreciated and understood by a person of ordinary skill in the art.

When an element is described as “not overlapping” or “will not overlap” another element, it may include the elements being spaced apart, offset, or separated from each other, or any other suitable term that will be appreciated and understood by a person of ordinary skill in the art.

The term “opposite to” means that a first element may be directly or indirectly opposite to a second element. In a case where a third element is provided between the first element and the second element, the first element and the second element may be understood as being indirectly opposite to each other although still opposite to each other.

In the embodiments of the present disclosure, the adopted transistors may be thin film transistors (TFTs), field effect transistors (e.g., metal oxide semiconductor transistors (MOS transistors)) or other switching devices with same characteristics. The embodiments of the present disclosure will all be described by taking the thin film transistors as an example.

Herein, a control electrode of each thin film transistor is a gate of the transistor, a first electrode of the thin film transistor is one of a source and a drain of the thin film transistor, and a second electrode of the thin film transistor is the other of the source and the drain of the thin film transistor. Since the source and the drain of the thin film transistor may be symmetrical in structure, there may be no difference in structure between the source and the drain. That is, there may be no difference in structure between the first electrode and the second electrode of the thin film transistor in the embodiments of the present disclosure. For example, in a case where the thin film transistor is a P-type transistor, a first electrode of the thin film transistor is a source, and a second electrode of the thin film transistor is a drain. For example, in a case where the thin film transistor is an N-type transistor, a first electrode of the thin film transistor is a drain, and a second electrode of the thin film transistor is a source.

In the embodiments of the present disclosure, a capacitor may be a capacitor device manufactured separately through a process procedure. For example, the capacitor device is realized by manufacturing specialized capacitor electrodes, and each capacitor electrode of the capacitor may be implemented by a metal layer, a semiconductor layer (e.g., doped polysilicon), or the like. The capacitor may alternatively be a parasitic capacitor between transistors, or implemented by the transistors and other devices or by the transistors and lines, or implemented by using the parasitic capacitor between lines of the circuit itself.

In the circuit provided by the embodiments of the present disclosure, nodes do not represent actual components, but represent junctions of related electrical connections in a circuit diagram. That is, these nodes are nodes equivalent to the junctions of the related electrical connections in the circuit diagram.

As shown in FIG. 1, some embodiments of the present disclosure provide a display apparatus 1000, and the display apparatus 1000 may be any apparatus that displays images whether in motion (such as a video) or fixed (such as a still image), and regardless of text or image.

For example, the display apparatus 1000 may be any product or component having a display function such as a television, a notebook computer, a tablet computer, a mobile phone, a personal digital assistant (PDA), a navigator, a car display, a flight display, a wearable device, a virtual reality (VR) device, a projector, or an electronic billboard or sign.

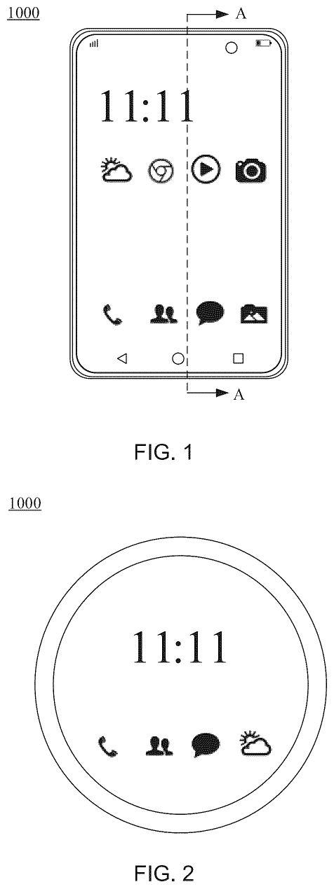

For example, as shown in FIG. 1, the display apparatus 1000 may be a portable display product; for example, the display apparatus 1000 is a mobile phone shown in FIG. 1. As another example, referring to FIG. 2, the display apparatus 1000 may be a wearable device; for example, the display apparatus 1000 is a watch shown in FIG. 2.

It will be noted that, depending on different application scenarios, the display apparatus 1000 may be a flat display apparatus, a curved display apparatus, a foldable display apparatus, and the like, and a display surface of the display apparatus 1000 may be in a shape of any of a circular, an elliptical, a polygonal or an irregular shape, which is not specifically limited in the embodiments of the present disclosure.

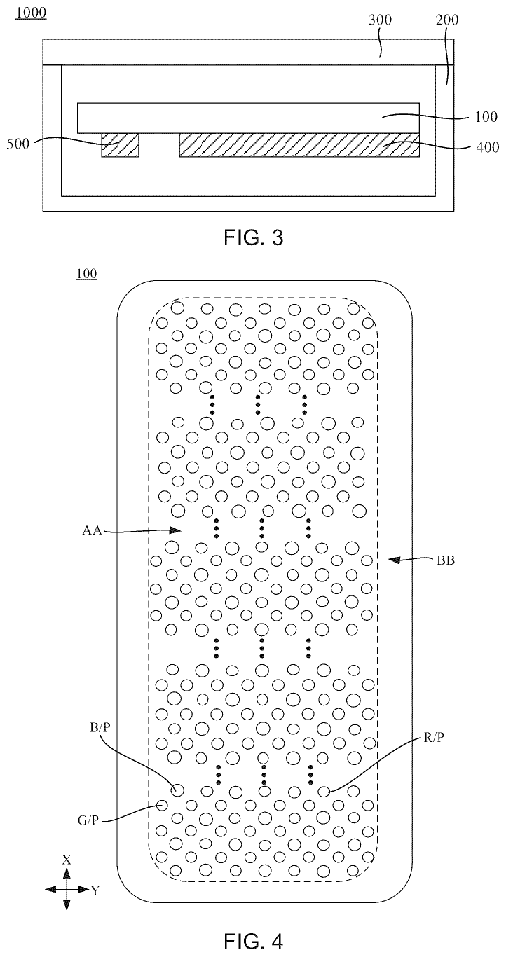

In some embodiments, referring to FIG. 3, the display apparatus 1000 includes a display panel 100, and the display panel 100 may, for example, include a display surface and a non-display surface that are disposed oppositely. The display surface refers to a surface of the display panel 100 for displaying an image, and the non-display surface refers to the other surface opposite to the display surface.

The type of the display panel 100 varies, which may be set according to actual needs. For example, the display panel 100 is an organic light-emitting diode (OLED) display panel, a quantum dot light-emitting diode (QLED) display panel, or a micro light-emitting diode (micro LED) display panel, which is not specifically limited in the embodiments of the present disclosure.

Some embodiments of the present disclosure will be exemplarily described below by considering an example in which the display panel 100 is an OLED display panel.

For example, referring to FIG. 3, the display apparatus 1000 may further include a housing 200, a cover plate 300, a circuit board 400, a photosensitive device 500, and other electronic components. The display panel 100, the circuit board 400 and the photosensitive device 500 may be disposed inside the housing 200.

For example, as shown in FIG. 3, the housing 200 may be of a box-shaped structure with an opening. The display panel 100, the circuit board 400 and the photosensitive device 500 may be provided in the housing 200, and the cover plate 300 is provided on a surface of the display panel 100 for displaying the image and is located at the opening of the housing 200.

The circuit board 400 may be bonded to the display panel 100 at an end of the display panel 100 and bent to a back side of the display panel 100, so as to shorten a frame of the display panel 100 and improve a screen-to-body ratio. The photosensitive device 500 may be integrated directly below the non-display surface of the display panel 100, so as to shorten the frame of the display panel 100 and improve the screen-to-body ratio.

It will be noted that the photosensitive device 500 may be a camera, an infrared sensor, a proximity sensor, an eye tracking module, a face recognition module, or the like, and the embodiments of the present disclosure do not specifically limit here.

In some embodiments, referring to FIG. 4, the display panel 100 has a display area AA and a peripheral area BB provided on at least one side of the display area AA. FIG. 4 shows an example in which the peripheral area BB is disposed around the display area AA.

Here, the display area AA is an area for displaying the image, and the display area AA is configured to be provided with sub-pixels P therein. The peripheral area BB is an area where no image is displayed, and the peripheral area BB is configured to be bonded to the circuit board 400 and be provided with driver circuit(s) therein. For example, the display panel 100 includes bonding pins, a gate driver circuit and a source driver circuit that are provided in the peripheral area BB.

For example, as shown in FIG. 4, the plurality of sub-pixels P may be arranged in a plurality of rows and a plurality of columns in the display area AA. The plurality of columns each include at least two sub-pixels P arranged in the first direction X, and the plurality of rows each include at least two sub-pixels P arranged in the second direction Y. For example, each column includes at least two sub-pixels P arranged in the first direction X, and each row includes at least two sub-pixels P arranged in the second direction Y. The first direction X intersects with the second direction Y. For example, the first direction X is perpendicular to the second direction Y.

Some embodiments of the present disclosure will be exemplarily described below by considering an example in which the first direction X is perpendicular to the second direction Y, but the embodiments of the present disclosure are not limited thereto.

In addition, the plurality of sub-pixels P may include, for example, a plurality of sub-pixels P with different luminous colors, and the plurality of sub-pixels P with different luminous colors interact with each other to achieve full-color display. For example, the plurality of sub-pixels P include red sub-pixels R with a luminous color of red, blue sub-pixels B with a luminous color of blue, and green sub-pixels G with a luminous color of green.

It can be understood that when full-color display is implemented, the arrangement of the red sub-pixels R, the blue sub-pixels B and the green sub-pixels G is not unique.

For example, as shown in FIG. 4, a plurality of red sub-pixels R and a plurality of blue sub-pixels B are arranged in an array of multiple rows and multiple columns, each column includes multiple red sub-pixels R and multiple blue sub-pixels B that are arranged alternately in the first direction X, and each row includes multiple red sub-pixels R and multiple blue sub-pixels B that are arranged alternately in the second direction Y. A plurality of green sub-pixels G are arranged in an array of multiple rows and multiple columns, and a green sub-pixel G is provided between red and blue sub-pixels R and B in each two rows and two columns arranged adjacent to each other. In this case, the arrangement of the red sub-pixel R, the blue sub-pixel B and the green sub-pixel G is first arrangement. The red sub-pixel R, the blue sub-pixel B and the green sub-pixel G are arranged in the first arrangement, and the display image is rather delicate and the display effect is relatively good.

It will be noted that geometric centers of sub-pixels P in the same column may be distributed on a plurality of straight lines that are parallel, and the first direction X is parallel to the straight lines; and geometric centers of sub-pixels P in the same row may be distributed on a plurality of straight lines that are parallel, and the second direction Y is parallel to the straight lines.

Some embodiments of the present disclosure will be exemplarily described below by taking an example where the plurality of sub-pixels P include red sub-pixels R, blue sub-pixels B and green sub-pixels G that are arranged in the first arrangement. However, implementation manners of the present disclosure are not limited thereto, and any other arrangements may also be considered as long as the same technical idea is applied.

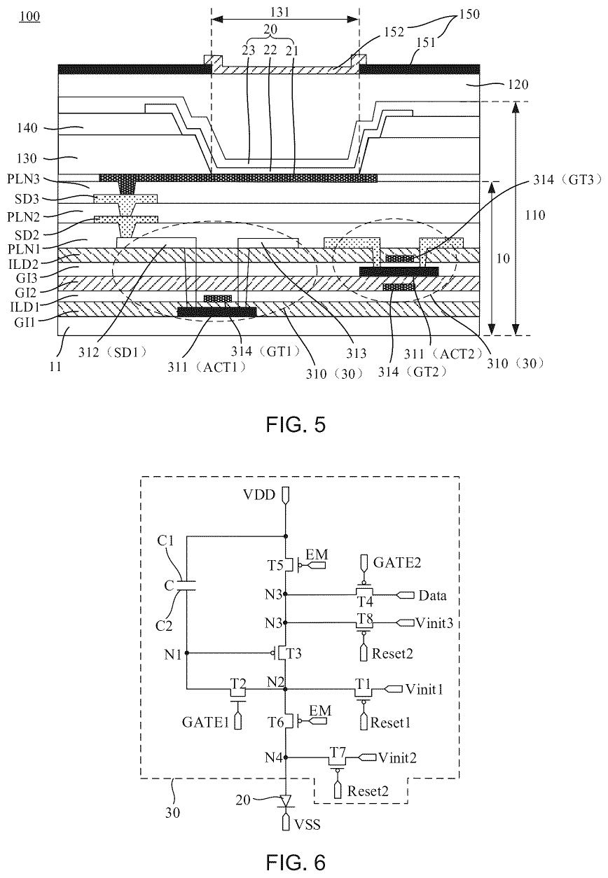

In some embodiments, as shown in FIG. 5, the display panel 100 includes a display substrate 110 and an encapsulation layer 120 disposed on a side of the display substrate 110, and the encapsulation layer 120 covers the display substrate 110 to reduce the risk of erosion of moisture and oxygen. The encapsulation layer 120 may be an encapsulation film or an encapsulation substrate.

In some embodiments, as shown in FIG. 5, the display panel 100 includes a display substrate 110 and an encapsulation layer 120 disposed on a side of the display substrate 110, and the encapsulation layer 120 covers the display substrate 110 to reduce the risk of erosion of moisture and oxygen. The encapsulation layer 120 may be an encapsulation film or an encapsulation substrate.

In some embodiments, as shown in FIG. 5, the display panel 100 further includes an anti-reflection film 150, and the anti-reflection film 150 is provided on a side of the encapsulation layer 120 away from the display substrate 110. The anti-reflection film 150 is configured to reduce a reflective intensity of external ambient light on the display panel 100.

In some examples, referring to FIG. 5, the anti-reflection film 150 includes a black matrix 151 and color films 152. The black matrix 151 is used to separate light emitted by different sub-pixels P (referring to FIG. 4), and has a function of reducing reflected light generated after the external ambient light enters the display panel 100. The color film 152 may filter out light of most wavelength bands in the external ambient light, thereby reducing the reflective intensity of the external ambient light on the display panel 100. In some other examples, the anti-reflection film 150 includes a polarizer, which is not specifically limited in the embodiments of the present disclosure.

In some embodiments, as shown in FIG. 5, the display substrate 110 includes an array substrate 10, and a light-emitting device 20, a pixel defining layer 130 and a spacer 140 that are disposed on a side of the array substrate 10.

The pixel defining layer 130 defines a plurality of pixel openings 131, and a light-emitting device 20 is disposed in a pixel opening 131. The spacer 140 is disposed between the pixel defining layer 130 and the encapsulation layer 120, and is located in a region between a plurality of light-emitting devices 20. In this way, during manufacturing the display panel 100, the spacer 140 may play a role in supporting a mask, so as to reduce scratches caused by direct contact between the mask and the pixel defining layer 130 or between the mask and the light-emitting device 20, thereby affecting the display effect.

In addition, the array substrate 10 includes a substrate 11 and a plurality of pixel circuits 30 disposed on the substrate 11. The light-emitting device 20 is connected to the pixel circuit 30 to receive a driving current signal to drive the light-emitting device 20 to emit light. In this case, a sub-pixel P includes a light-emitting device 20 and a pixel circuit 30 for driving the light-emitting device 20.

The substrate 11 may be a rigid substrate. For example, the rigid substrate is a glass substrate or a polymethyl methacrylate (PMMA) substrate.

The substrate 11 may be a flexible substrate. For example, the flexible substrate is a polyethylene terephthalate (PET) substrate, a polyethylene naphthalate (polyethylene naphthalate two formic acid glycol ester, PEN) substrate or a polyimide (PI) substrate.

As shown in FIGS. 5 and 6, the light-emitting device 20 includes a light-emitting functional layer 22, and a first electrode 21 and a second electrode 23 that are disposed on opposite sides of the light-emitting functional layer 22. The first electrode 21 is closer to the array substrate 10. The first electrode 21 may be, for example, connected to the pixel circuit 30, and the second electrode 22 may be, for example, connected to a second voltage signal terminal VSS.

In some implementations, the light-emitting functional layer 22 only includes a light-emitting layer. In some other implementations, in addition to the light-emitting layer, the light-emitting functional layer 22 further includes at least one of an electron transport layer (ETL), an electron injection layer (EIL), a hole transport layer (HTL) and a hole injection layer (HIL).

It will be noted that, of the first electrode 21 and the second electrode 23, one is an anode and the other is a cathode, which is not specifically limited in the embodiments of the present disclosure.

As shown in FIGS. 5 and 6, the pixel circuit 30 includes a plurality of transistors 310. The transistor 310 includes a channel 311, a first electrode 312, a second electrode 313, and a control electrode 314. The first electrode 312 and the second electrode 313 are both connected to the channel 311. On this basis, the first electrode 21 is in electrical contact with a first electrode 312 or a second electrode 313 of a transistor 310 of the plurality of transistors 310. FIG. 5 shows an example where the first electrode 21 is in electrical contact with the first electrode 312 of the transistor 310.

In some embodiments, referring to FIG. 6, the pixel circuit 30 includes a capacitor C, a first reset transistor T1 and a compensation transistor T2.

In combination with FIGS. 5 and 6, a first electrode plate C1 of the capacitor C is connected to a first voltage signal terminal VDD, and a second electrode plate C2 of the capacitor C is connected to a first node N1. A control electrode 314 of the first reset transistor T1 is connected to a first reset signal terminal Reset1, a first electrode 312 of the first reset transistor T1 is connected to a first initial signal terminal Vinit1, and a second electrode 313 of the first reset transistor T1 is connected to a second node N2. A control electrode 314 of the compensation transistor T2 is connected to a first scanning signal terminal GATE1, a first electrode 312 of the compensation transistor T2 is connected to the second node N2, and a second electrode 313 of the compensation transistor T2 is connected to the first node N1.

For example, as shown in FIGS. 5, 6, 7 and 8, the array substrate 10 includes a plurality of first connection lines 40 and a plurality of second connection lines 50. The plurality of first connection lines 40 extend in the first direction X. An end of the first connection line 40 is connected to the second electrode plate C2 of the capacitor C, and the other end of the first connection line 40 is connected to the second electrode 313 of the compensation transistor T2. The plurality of second connection lines 50 extend in the first direction X. An end of the second connection line 50 is connected to the second electrode 313 of the first reset transistor T1, and the other end of the second connection line 50 is connected to the first electrode 312 of the compensation transistor T2.

It will be understood that the structure of the pixel circuit 30 varies, which may be set according to actual needs. A structure and an operating process of the pixel circuit 30 will be exemplarily illustrated by taking an example in which an external compensation method is adopted and the pixel circuit 30 adopts a 8T1C structure in embodiments of the present disclosure. Here, “T” represents a transistor, the number in front of “T” represents the number of transistors, “C” represents a capacitor, and the number in front of “C” represents the number of capacitors.

The pixel circuit 30 further includes a driving transistor T3, a data write transistor T4, a first enabling transistor T5, a second enabling transistor T6, a second reset transistor T7 and a third reset transistor T8.

In the pixel circuit 30 in the embodiments of the present disclosure, the thin film transistors 310 may be P-type transistors or N-type transistors.

Some embodiments of the present disclosure will be exemplarily described below by taking an example where the first reset transistor T1, the driving transistor T3, the data write transistor T4, the first enabling transistor T5, the second enabling transistor T6, the second reset transistor T7 and the third reset transistor T8 are P-type transistors, and the compensation transistor T2 is an N-type transistor, but the embodiments of the present disclosure are not limited thereto.

As shown in FIGS. 5 and 6, a control electrode 314 of the driving transistor T3 is connected to the first node N1, a first electrode 312 of the driving transistor T3 is connected to a third node N3, and a second electrode 313 of the driving transistor T3 is connected to the second node N2.

As shown in FIGS. 5 and 6, a control electrode 314 of the data write transistor T4 is connected to a second scanning signal terminal GATE2, a first electrode 312 of the data write transistor T4 is connected to a data signal terminal Data, and a second electrode 313 of the data write transistor T4 is connected to the third node N3.

As shown in FIGS. 5 and 6, a control electrode 314 of the first enabling transistor T5 is connected to an enabling signal terminal EM, a first electrode 312 of the first enabling transistor T5 is connected to the first voltage signal terminal VDD, and a second electrode 313 of the first enabling transistor T5 is connected to the third node N3.

As shown in FIGS. 5 and 6, a control electrode 314 of the second enabling transistor T6 is connected to the enabling signal terminal EM, a first electrode 312 of a second enabling transistor T6 is connected to the second node N2, and a second electrode 313 of the second enabling transistor T6 is connected to the fourth node N4. It will be noted that the first electrode 21 of the light-emitting device 20 is connected to the fourth node N4.

As shown in FIGS. 5 and 6, a control electrode 314 of the second reset transistor T7 is connected to a second reset signal terminal Reset2, a first electrode 312 of the second reset transistor T7 is connected to a second initial signal terminal Vinit2, and a second electrode 313 of the second reset transistor T7 is connected to the fourth node N4.

As shown in FIGS. 5 and 6, a control electrode 314 of the third reset transistor T8 is connected to the second reset signal terminal Reset2, a first electrode 312 of the third reset transistor T8 is connected to a third initial signal terminal Vinit3, and a second electrode 313 of the third reset transistor T8 is connected to the third node N3.

Based on this, the first reset transistor T1, the driving transistor T3, the data writing transistor T4, the first enabling transistor T5, the second enabling transistor T6, the second reset transistor T7 and the third reset transistor T8 may be, for example, low-temperature polysilicon transistors; and the compensation transistor T2 may be, for example, an oxide transistor.

It will be understood that an active layer of the low-temperature polysilicon transistor adopts low-temperature polysilicon (low temperature poly-silicon, LTPS), and the low-temperature polysilicon transistor has high mobility, fast charging, and other advantages. An active layer of the oxide transistor adopts an oxide semiconductor, such as indium gallium zinc oxide or indium gallium tin oxide, and the oxide transistor has an advantage of low leakage current.

Based on this, the low-temperature polysilicon transistors and the oxide transistors are integrated into the array substrate 10, so as to form a low-temperature polycrystalline oxide (LTPO) array substrate 10. As a result, advantages of the low-temperature polysilicon transistors and the oxide transistors may be used to reduce the leakage current, reduce power consumption, achieve low-frequency driving, and improve display quality.

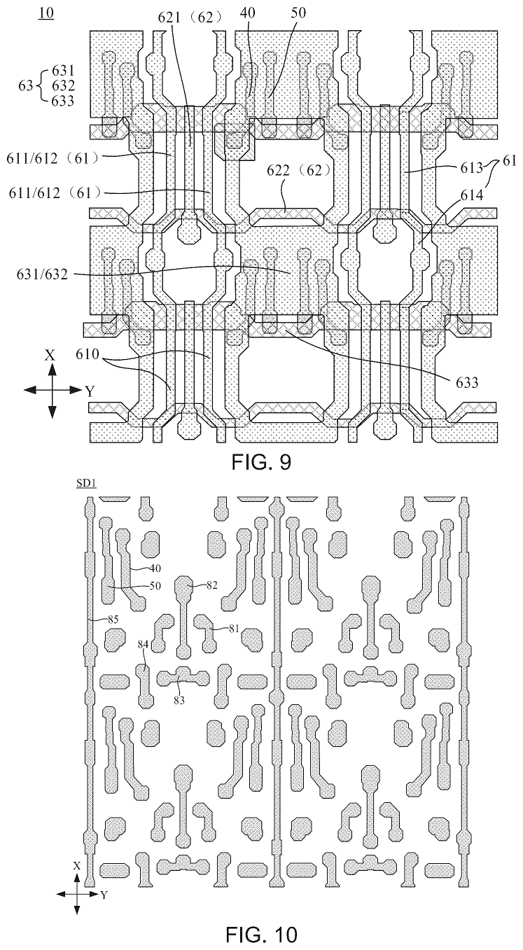

In some embodiments, referring to FIG. 9, the array substrate 10 further includes a plurality of first data lines 61. The plurality of first data lines 61 extend in the first direction X and are arranged at intervals in the second direction Y. In combination with FIGS. 6 and 9, a first data line 61 may be, for example, connected to data signal terminals Data of pixel circuits 30 in a column to transmit a data signal.

In this case, a first connection line 40 and a second connection line 50 are located between two adjacent first data lines 61, and in the second direction Y, the first connection line 40 is closer to one of the two first data lines 61, and the second connection line 50 is located on a side of the first connection line 40 away from the first data line 61 to which the first connection line 40 is closer to.

In some related arts, the smaller the spacing between the first data line and the first connection line, and larger the parasitic capacitance between the first data line and the first connection line, resulting in increased crosstalk between the first data line and the capacitor connected to the first connection line, thereby causing the display effect of the display panel to decrease.

In light of this, in the array substrate 10 provided in some embodiments of the present disclosure, referring to FIG. 9, in the second direction Y, the maximum distance between a first connection line 40 and a second connection line 50 that are adjacent is less than or equal to 2.4 μm.

For example, in the second direction Y, the distance between the first connection line 40 and the second connection line 50 that are adjacent is in a range of 1 μm to 2.4 μm, inclusive. For example, in the second direction Y, the distance between the first connection line 40 and the second connection line 50 that are adjacent is approximately any of 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm and 2.4 μm.

In this case, in the second direction Y, the distance between the first connection line 40 and the second connection line 50 that are adjacent may be reduced, that is, the first connection line 40 may be offset in a direction toward the second connection line 50, so as to increase the distance in the second direction Y between the first connection line 40 and the first data line 61 to which the first connection line 40 is closer. The increased distance may, for example, reach a range of 1.6 μm to 3.1 μm.

It can be known according to the capacitance calculation formula that in the second direction Y, the distance between the first connection line 40 and the first data line 61 to which the first connection line 40 is closer increases, and the parasitic capacitance between the first connection line 40 and the first data line 61 to which the first connection line 40 is closer decreases, and thus the crosstalk between the capacitor C connected to the first connection line 40 and the first data line 61 to which the first connection line 40 is closer may be reduced, thereby improving the display effect. Compared with the related art, in the array substrate 10 provided by some embodiments of the present disclosure, the parasitic capacitance between the first connection line 40 and the first data line 61 to which the first connection line 40 is closer may be reduced by approximately 0.13 fF.

In some embodiments, referring to FIGS. 5 and 10, the array substrate 10 includes a first source-drain conductive layer SD1. The first source-drain conductive layer SD1 is disposed on a side of the substrate 11 proximate to the pixel circuit 30. The first connection lines 40 and the second connection lines 50 may be located in the first source-drain conductive layer SD1.

As shown in FIGS. 5, 6, 10 and 11, the first source-drain conductive layer SD1 may further include third connection lines 81 and fourth connection lines 82. The third connection lines 81 extend in the first direction X. An end of the third connection line 81 is connected to the second electrode 313 of the first enabling transistor T5, and the other end of the third connection line 81 is connected to the second electrode 313 of the third reset transistor T8. The fourth connection lines 82 extend in the first direction X. An end of the fourth connection line 82 is connected to the first electrode 312 of the first enabling transistor T5, and the other end of the fourth connection line 82 is connected to the first electrode plate C1 of the capacitor C.

In addition, as shown in FIG. 10, the first source-drain conductive layer SD1 may further include fifth connection lines 83, sixth connection lines 84 and seventh connection lines 85.

As shown in FIGS. 5, 6, 10 and 11, the fifth connection lines 83 extend in the second direction Y. Both ends of the fifth connection line 83 are connected to the first electrode 312 of the third reset transistor T8, and the fifth connection line 83 is also connected to a third initial signal line 75.

As shown in FIGS. 5, 6, 10 and 11, the sixth connection lines 84 extend in the first direction X. An end of the sixth connection line 84 is connected to the first electrode 312 of the second reset transistor T7, and the other end of the sixth connection line 84 is connected to a second initial signal line 74.

As shown in FIGS. 5, 6, 10 and 11, the seventh connection lines 85 extend in the first direction X. A seventh connection line 85 is connected to any of a plurality of first initial signal lines 73, a plurality of second initial signal lines 74 and a plurality of third initial signal lines 75 to reduce resistance, so as to reduce voltage drops of initial signals transmitted by the first initial signal lines 73, the second initial signal lines 74 and the third initial signal lines 75, thereby improving the brightness uniformity.

It will be noted that for the first initial signal lines 73, the second initial signal lines 74 and the third initial signal lines 75, reference may be made specifically to the following text, and the implementations of the present disclosure do not describe in detail here.

In some embodiments, referring to FIG. 9, the array substrate 10 further includes a plurality of first power signal lines 63. The first power signal lines 63 are made of the same material and provided in the same layer as the first data lines 61, and/or, the first power signal lines 63 are located between a film layer where the first data lines 61 are located and a film layer where the first connection lines 40 are located.

An orthographic projection of the first connection line 40 on a reference plane is located within an orthographic projection of the plurality of first power signal lines 63 on the reference plane. In this way, the first power signal line 63 may play a role of electromagnetic shielding to reduce the crosstalk between a capacitor C connected to the first connection line 40 and a first data line 61 to which the first connection line 40 is closer, thereby improving the display effect. It will be noted that the reference plane is a plane determined by the first direction X and the second direction Y.

For example, referring to FIGS. 9, 12 and 13, the plurality of first power signal lines 63 include a plurality of first power sub-lines 631, a plurality of second power sub-lines 632 and a plurality of third power sub-lines 633.

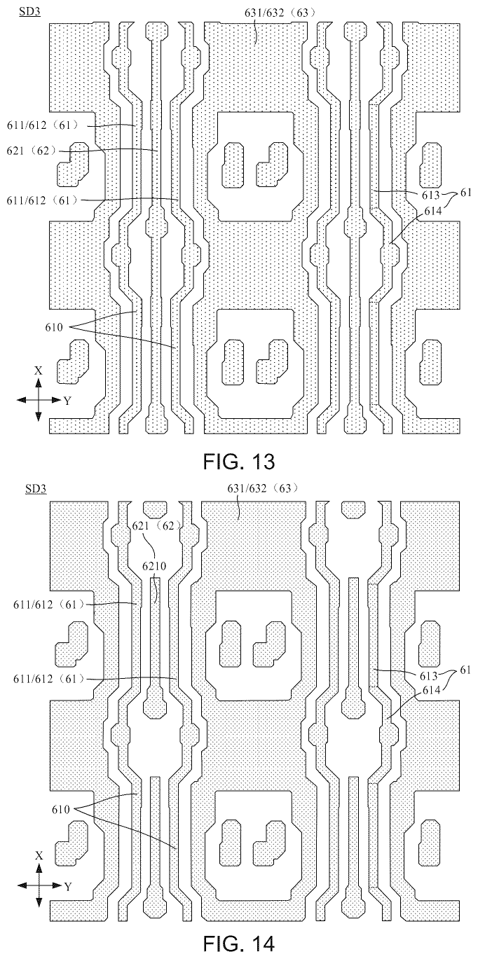

As shown in FIGS. 9 and 13, the first power sub-line 631 is configured to receive a power signal provided from the circuit board 400. For example, the plurality of first power sub-lines 631 extend in the first direction X and are arranged at intervals in the second direction Y. An end of the first power sub-line 631 is directly connected to a bonding pin, that is, the end of the first power sub-line 631 is directly connected to the circuit board 400 by the bonding pin to receive the power signal.

Here, in the plurality of first power sub-lines 631, some first power sub-lines 631 may each also be directly connected to a first voltage signal terminal VDD (referring to FIG. 6) of a column of pixel circuits 30, and other first power sub-lines 631 are not directly connected to a first voltage signal terminal VDD (referring to FIG. 6) of a column of pixel circuits 30, but are each connected to a corresponding second power sub-lines 632 by a third power sub-line 633, and the second power sub-line 632 is directly connected to a first voltage signal terminal VDD (referring to FIG. 6) of a column of pixel circuits 30.

As shown in FIGS. 9 and 13, the second power sub-line 632 is configured to provide a power signal to the first voltage signal terminal VDD of the pixel circuit 30. For example, the second power sub-lines 632 extend in the first direction X and are arranged at intervals in the second direction Y. A second power sub-line 632 may be directly connected to a first voltage signal terminal VDD (referring to FIG. 6) of a column of pixel circuits 30.

Here, the second power sub-line 632 is not directly connected to a bonding pin, but is connected to a first power sub-line 631 by a third power sub-line 633 to receive the power signal. Here, the first power sub-line 631 connected to the third power sub-line 633 is not directly connected to the first voltage signal terminal VDD (referring to FIG. 6) of the pixel circuit 30.

As shown in FIGS. 9, 12 and 13, a second power sub-line 632 is connected to a first power sub-line 631. For example, the third power sub-lines 633 extend in the second direction Y and are arranged at intervals in the first direction X. A second power sub-line 632 is connected to a first power sub-line 631 by a third power sub-line 633.

On this basis, part of the orthographic projection of the first connection line 40 on the reference plane is located within an orthographic projection of the first power sub-line 631 or the second power sub-line 632 on the reference plane, and the other part of the orthographic projection of the first connection line 40 on the reference plane is located within an orthographic projection of the third power sub-line 633 on the reference plane.

Referring to FIGS. 5 and 9, the array substrate 10 may further include a second source-drain conductive layer SD2 and a third source-drain conductive layer SD3. The second source-drain conductive layer SD2 is disposed on a side of the first source-drain conductive layer SD1 away from the substrate 11, and the third source-drain conductive layer SD3 is disposed on a side of the second source-drain conductive layer SD2 away from the substrate 11. In this case, the third power sub-line 633 may be located in the second source-drain conductive layer SD2, and the first data lines 61, the first power sub-line 631 and the second power sub-line 632 may be located in the third source-drain conductive layer SD3.

In some embodiments, referring to FIG. 9, the array substrate 10 may further include a plurality of second data lines 62. The plurality of first data lines 61 include first-type data lines 611 and second-type data lines 612.

As shown in FIGS. 6 and 9, the first-type data line 611 is directly connected to the driver circuit, and is directly connected to a data signal terminal Data of a column of pixel circuits 30 to provide a data signal to the pixel circuits 30. A second-type data line 612 is directly connected to a data signal terminal Data of a column of pixel circuits 30, and is connected to the driver circuit by a second data line 62.

For example, referring to FIGS. 9, 12 and 13, the second data line 62 includes a first data sub-line 621 and a second data sub-line 622. A plurality of first data sub-lines 621 extend in the first direction X and are arranged at intervals in the second direction Y. A plurality of second data sub-lines 622 extend in the second direction Y and are arranged at intervals in the first direction X. The first data sub-line 621 is directly connected to the driver circuit, and a first data sub-line 621 is connected to a second-type data line 612 by a second data sub-line 622 to transmit a data signal to the second-type data line 612.

In this case, the second data sub-line 622 may be located in the second source-drain conductive layer SD2. The first data sub-line 621 may be located in the third source-drain conductive layer SD3. For example, as shown in FIG. 13, the first data sub-line 621 is directly connected to the driver circuit without transferring or avoiding.

Alternatively, a part of the first data sub-line 621 is located in the second source-drain conductive layer SD2, and the other part of the first data sub-line 621 is located in the third source-drain conductive layer SD3. For example, as shown in FIG. 14, the first data sub-line 621 includes main segments 6210 and transition segments. The main segments 6210 are spaced apart in the first direction X to form avoidance areas, and the avoidance areas may be configured as light-transmitting areas, so as to facilitate lighting of the photosensitive device 500 at a non-light-emitting side of the display panel 100.

It will be noted that the main segments 6210 may be located in the third source-drain conductive layer SD3, and the transition segments may be located in the second source-drain conductive layer SD2, which is not specifically limited in the embodiments of the present disclosure.

In some embodiments, referring to FIGS. 9, 13, and 14, the plurality of first data lines 61 are divided into a plurality of data line groups 610, and each data line group 610 includes two first data lines 61. In this case, the above first data sub-lines 621 may be located between two first data lines 61 in the same data line group 610.

The plurality of first data line 61 each include first straight segments 613 and bent segments 614 that are alternately connected. The plurality of first data lines 61 are divided into a plurality of data line groups 610, and each data line group 610 includes two first data lines 61. Bent segments 614 of two first data lines 61 in the same data line group 610 are provided oppositely and bent toward directions away from each other to form an avoidance area, and the avoidance area may be configured as a light-transmitting area, so as to facilitate lighting of the photosensitive device 500 at a non-light-emitting side of the display panel 100.

In this case, the first connection line 40 and the second connection line 50 are located between two first data lines 61 that belong to different data line groups 610 and are adjacent. Moreover, in the second direction Y, the first connection line 40 is at least partially opposite to the bent segment 614, and opposite edges of a portion of the first connection line opposite to the bent segment and an adjacent second connection line 50 are parallel.

It will be noted that “opposite edges of the portion of the first connection line 40 opposite to the bent segment 614 and the adjacent second connection line 50” do not include portions of ends of the first connection line 40 and the second connection line 50 bent away from each other.

It will be understood that in the second direction Y, a portion of the first connection line 40 closer to the first data line 61 is the portion of the first connection line 40 opposite to the bent segment 614. The opposite edges of the portion of the first connection line 40 opposite to the bent segment 614 and the adjacent second connection line 50 are parallel, so that a distance between the portion of the first connection line 40 closer to the first data line 61 and the adjacent second connection line 50 may be set to a process limit value, so as to reduce a distance between the first connection line 40 and the second connection line 50, increase a distance between the first connection line 40 and the first data line 61, and reduce the parasitic capacitance between the first connection line 40 and the first data line 61 to which the first connection line 40 is closer, thereby reducing the crosstalk between the capacitor C connected to the first connection line 40 and the first data line 61 to which the first connection line 40 is closer, and improving the display effect.

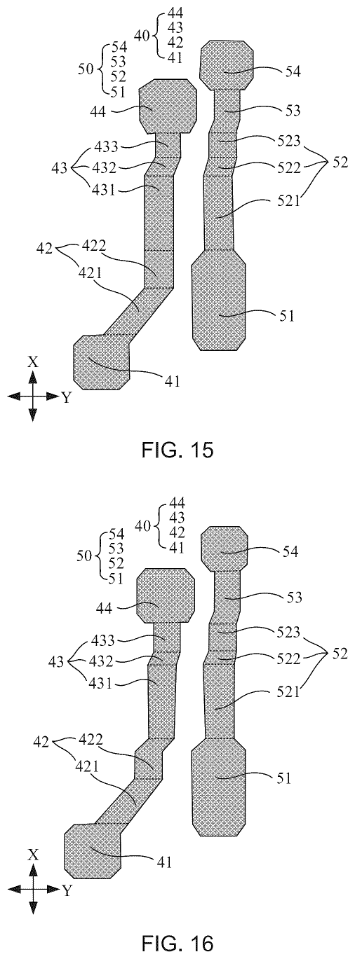

For example, as shown in FIGS. 15 and 16, the first connection line 40 includes a first connection pad 41, a first routing segment 42, a second routing segment 43 and a second connection pad 44 connected in sequence, and the second connection line 50 includes a third connection pad 51, a third routing segment 52, a fourth routing segment 53 and a fourth connection pad 54 connected in sequence.

In addition, in combination with FIGS. 5, 6, 11 and 17, the first connection pad 41 is connected to the second electrode plate C2 of the capacitor C, and the second connection pad 44 is connected to the second electrode 313 of the compensation transistor T2. The third connection pad 51 is connected to the first electrode 312 of the compensation transistor T2, and the fourth connection pad 54 is connected to the second electrode 313 of the first reset transistor T1.

It will be noted that each of shapes of the first connection pad 41, the second connection pad 44, the third connection pad 51 and the fourth connection pad 54 include at least one of a polygon, a circle and an ellipse, which is not specifically limited in the embodiments of the present disclosure.

On this basis, as shown in FIGS. 15 and 16, the first routing segment 42 extends toward a direction close to the adjacent second connection line 50, and is located on a side of the third routing segment 52 away from the fourth connection pad 54. In the second direction Y, the first routing segment 42 is opposite to the third connection pad 51, the second routing segment 43 is opposite to the third routing segment 52, and the fourth routing segment 53 is opposite to the second connection pad 44.

Moreover, opposite edges of the second routing segment 43 and the third routing segment 52 are parallel, and opposite edges of the second connection pad 44 and the fourth routing segment 53 are parallel, so that a distance between both the second routing segment 43 and the second connection pad 44 and routing segments of the adjacent second connection line 50 may be set to the process limit value, so as to reduce a distance between both the second routing segment 43 and the second connection pad 44 and the routing segments of the second connection line 50, increase a distance between both the second routing segment 43 and the second connection pad 44 and the first data line 61, and reduce the parasitic capacitance between both the second routing segment 43 and the second connection pad 44 and the first data line 61 to which the second routing segment 43 and the second connection pad 44 are closer, thereby reducing the crosstalk between the capacitor C connected to the first connection line 40 and the first data line 61 to which the first connection line 40 is closer, and improving the display effect. In this case, the portion of the first connection line 40 opposite to the bent segment 614 may include the second connection pad 44 and the second routing segment 43.

In addition, as shown in FIGS. 15 and 16, in the second direction Y, the fourth routing segment 53 may, for example, be opposite to a portion of the second connection pad 44, and the fourth connection pad 54 may, for example, be opposite to another portion of the second connection pad 44. Furthermore, orthographic projections of the second connection pad 44 and the fourth connection pad 54 on the reference plane may each be, for example, in a shape of a polygon.

In this case, opposite edges of the second connection pad 44 and the fourth connection pad 54 may also be parallel, so that in a case where the second connection pad 44 and the fourth connection pad 54 are partially opposite to each other, a distance between the second connection pad 44 and the fourth connection pad 54 may be set to a process limit value, which is beneficial to increase a distance between the second connection pad 44 and the first data line 61, and reduce the parasitic capacitance between the second connection pad 44 and the first data line 61 to which the second connection pad 44 is closer, thereby reducing the crosstalk between the capacitor C connected to the first connection line 40 and the first data line 61 to which the first connection line 40 is closer, and improving the display effect.

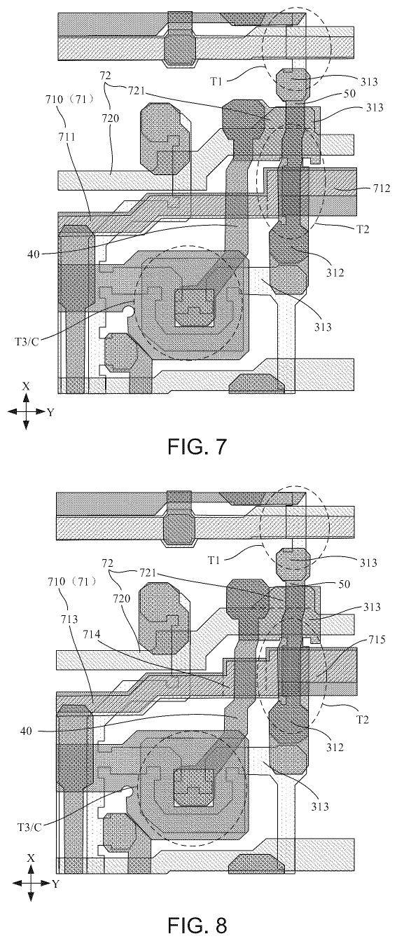

In some embodiments, referring to FIGS. 7, 8 and 11, in the same pixel circuit 30, in the first direction X, a channel 311 of the first reset transistor T1 is located on a side of a channel 311 of the driving transistor T3, and the second electrode 313 of the first reset transistor T1 is farther away from the adjacent first data line 61 than the second electrode 313 of the driving transistor T3.

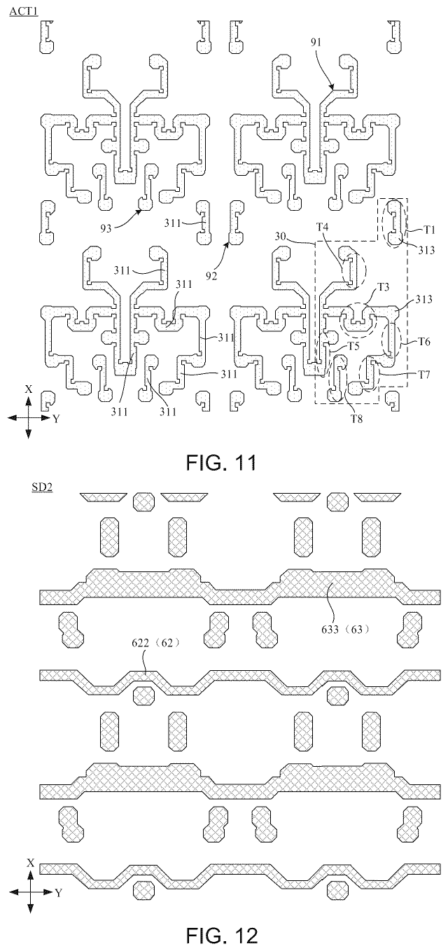

For example, referring to FIGS. 5 and 11, the array substrate 10 further includes a first active layer ACT1, and the first active layer ACT1 is disposed between the substrate 11 and the first source-drain conductive layer SD1. The first active layer ACT1 includes a plurality of first active patterns 91, a plurality of second active patterns 92 and a plurality of third active patterns 93.

As shown in FIGS. 5 and 11, the first active pattern 91 includes a channel 311, a first electrode 312 and a second electrode 313 of the driving transistor T3, a channel 311, a first electrode 312 and a second electrode 313 of the data writing transistor T4, a channel 311, a first electrode 312 and a second electrode 313 of the first enabling transistor T5, a channel 311, a first electrode 312 and a second electrode 313 of the second enabling transistor T6 and a channel 311, a first electrode 312 and a second electrode 313 of the second reset transistor T7.

As shown in FIGS. 5 and 11, the second active pattern 92 includes a channel 311, a first electrode 312 and a second electrode 313 of the first reset transistor T1. The plurality of first active patterns 91 and the plurality of second active patterns 92 are alternately arranged in the first direction X, and the second active pattern 92 is farther away from a corresponding first data line 61 than a corresponding first active pattern 91.

As shown in FIGS. 5 and 11, the third active pattern 93 includes a channel 311, a first electrode 312 and a second electrode 313 of the third reset transistor T8. In the second direction Y, the third active pattern 93 is located on a side of the channel 311 of the second reset transistor T7 proximate to the channel 311 of the first enabling transistor T5.

In this case, as shown in FIGS. 8, 9, 15 and 16, the third routing segment 52 may, for example, include a fourth sub-segment 521, a fifth sub-segment 522 and a sixth sub-segment 523 connected in sequence. The fourth sub-segment 521 is connected to the third connection pad 51, the sixth sub-segment 523 is connected to the fourth routing segment 53, and the sixth sub-segment 523 is farther away from the closer first data line 61 than the fourth sub-segment 521, so as to connect the second electrode 313 of the first reset transistor T1 with the second electrode 313 of the driving transistor T3.

Based on the fact that the opposite edges of the second routing segment 43 and the third routing segment 52 are parallel, the second routing segment 43 may, for example, include a first sub-segment 431, a second sub-segment 432 and a third sub-segment 433 connected in sequence. The first sub-segment 431 is connected to the first routing segment 42, and the third sub-segment 433 is connected to the second connection pad 44. In the second direction, the first sub-segment 431 is opposite to the fourth sub-segment 521, the second sub-segment 432 is opposite to the fifth sub-segment 522, and the third sub-segment 433 is opposite to the sixth sub-segment 523. The third sub-segment 433 is farther away from the closer first data line 61 than the first sub-segment 431.

In some embodiments, referring to FIGS. 9, 15 and 16, in the first direction X, opposite edges of the first routing segment 42 and the adjacent second connection line 50 are at least partially parallel. That is, opposite edges of the first routing segment 42 and the adjacent third connection pad 51 are also at least partially parallel, which is beneficial to increasing a distance between the first routing segment 42 and the first data line 61, reduce the parasitic capacitance between the first routing segment 42 and the first data line 61 to which the first routing segment 42 is closer, thereby reducing the crosstalk between the capacitor C connected to the first connection line 40 and the first data line 61 to which the first connection line 40 is closer, and improving the display effect.

For example, referring to FIGS. 15 and 16, the first routing segment 42 includes a seventh sub-segment 421 and an eighth sub-segment 422. The seventh sub-segment 421 is connected to the first connection pad 41 and extends toward a direction close to the adjacent second connection line 50. The eighth sub-segment 422 is connected to the second routing segment 43. For example, as shown in FIG. 15, the eighth sub-segment 422 is parallel to an edge of the third connection pad 51 extending in the first direction X. As another example, as shown in FIG. 16, opposite edges of the eighth sub-segment 422 and the third connection pad 51 are parallel.

In some embodiments, referring to FIGS. 7, 8 and 9, an orthographic projection of an edge of the first connection line 40 proximate to the first data line 61 to which the first connection line 40 is closer on the reference plane coincides with an orthographic projection of an edge of the second electrode 313 of the compensation transistor T2, connected to the first connection line 40, proximate to the corresponding first data line 61 on the reference plane. The “corresponding first data line 61” is a first data line 61 to which the first connection line 40 connected to the second electrode 313 of the compensation transistor T2 is closer.

For example, referring to FIG. 18, the array substrate 10 further includes a second active layer ACT2, and the second active layer ACT2 is disposed between the first active layer ACT1 and the first source-drain conductive layer SD1. The second active layer ACT2 includes a plurality of fourth active patterns 94, and the fourth active patterns 94 include a channel 311, a first electrode 312 and a second electrode 313 of the compensation transistor T2.

As shown in FIGS. 7, 9, 11 and 18, in the first direction X, the fourth active pattern 94 is located between a first active pattern 91 and a second active pattern 92 that are adjacent. An orthographic projection of an edge of a fourth active pattern 94 proximate to the corresponding first data line 61 on the reference plane coincides with an orthographic projection of an edge of the first connection line 40 connected to the fourth active pattern 94 proximate to the closer first data line 61 on the reference plane.

In a case where the second electrode 313 of the compensation transistor T2 forms a good electrical connection with the first connection line 40, a distance between the second electrode 313 of the compensation transistor T2 and the first data line 61 to which the compensation transistor T2 is closer is set relatively large, which is beneficial to reducing the parasitic capacitance between the second electrode 313 of the compensation transistor T2 and the first data line 61 to which the compensation transistor T2 is closer, thereby further reducing the crosstalk between the capacitor C connected to the first connection line 40 and the first data line 61 to which the first connection line 40 is closer, and improving the display effect.

In some embodiments, referring to FIGS. 6, 7, 18 and 19, the array substrate 10 further includes a plurality of first scanning signal lines 71. The first scanning signal lines 71 extend in the second direction Y and are each connected to a first scanning signal terminal GATE1 of a row of pixel circuits 30. Furthermore, an orthographic projection of the first scanning signal line 71 on the reference plane overlaps with an orthographic projection of the channel 311 of the compensation transistor T2 on the reference plane to form the control electrode 314 of the compensation transistor T2 (referring to FIG. 5).

Referring to FIG. 7, orthographic projections of the first scanning signal line 71 and the first connection line 40 on the reference plane overlap, and any edge of the overlapping portion is parallel to the first direction X or the second direction Y. In this way, a difference in overlapping area between different first connection lines 40 and first scanning signal lines 71 caused by process deviation may be reduced, and the brightness uniformity of the plurality of sub-pixels P (referring to FIG. 4) may be improved, thereby improving the display effect.

For example, referring to FIGS. 7 and 18, the first scanning signal line 71 includes a plurality of first scanning routing segments 710 connected in sequence. The first scanning routing segment 710 includes a first scanning sub-segment 711 and a second scanning sub-segment 712 connected in sequence. An orthographic projection of the first scanning sub-segment 711 on the reference plane overlaps with the orthographic projection of the first connection line 40 on the reference plane, and an orthographic projection of the second scanning sub-segment 712 on the reference plane overlaps with an orthographic projection of the channel 311 of the compensation transistor T2 on the reference plane.

A routing width of the first scanning sub-segment 711 remains substantially unchanged, and a routing width of the second scanning sub-segment 712 remains substantially unchanged. In the first direction X, the width of the first scanning sub-segment 711 is smaller than the width of the second scanning sub-segment 712, and an edge connecting the second scanning sub-segment 712 and the first scanning sub-segment 711 is parallel to an opposite edge of the first connection line 40, that is, the connection between the first scanning sub-segment 711 and the second scanning sub-segment 712 is a vertical mutation rather than a gradual transition. In this way, a difference in overlapping area between different first connection lines 40 and first scanning signal lines 71 caused by process deviation may be reduced, and the brightness uniformity of the plurality of sub-pixels P may be improved, thereby improving the display effect.

For example, referring to FIGS. 8 and 18, the first scanning signal line 71 includes a plurality of first scanning routing segments 710 connected in sequence. The first scanning routing segment 710 includes a third scanning sub-segment 713, a fourth scanning sub-segment 714 and a fifth scanning sub-segment 715 connected in sequence. An orthographic projection of the fourth scanning sub-segment 714 on the reference plane overlaps with the orthographic projection of the first connection line 40 on the reference plane, and an orthographic projection of the fifth scanning sub-segment 715 on the reference plane overlaps with the orthographic projection of the channel 311 of the compensation transistor T2 on the reference plane.

A routing width of the third scanning sub-segment 713 remains substantially unchanged, a routing width of the fourth scanning sub-segment 714 remains substantially unchanged, and a routing width of the fifth scanning sub-segment 715 remains substantially unchanged. In the first direction X, the width of the third scanning sub-segment 713 is smaller than the width of the fourth scanning sub-segment 714, and the width of the fourth scanning sub-segment 714 is smaller than the width of the fifth scanning sub-segment 715. In this way, an overlapping area between the first scanning signal line 71 and the first connection line 40 may increase, so as to reduce an influence of process fluctuation on offset of characteristics of the driving transistor T3 and reduce an influence of the offset of characteristics of the driving transistor T3 on the image quality, thereby improving the display effect.

On this basis, an edge connecting the fourth scanning sub-segment 714 and the third scanning sub-segment 713 is parallel to an opposite edge of the first connection line 40; and/or, an edge connecting the fifth scanning sub-segment 715 and the fourth scanning sub-segment 714 is parallel to an opposite edge of the first connection line 40. That is, the connection between the third scanning sub-segment 713, the fourth scanning sub-segment 714 and the fifth scanning sub-segment 715 is a vertical mutation rather than a gradual transition. In this way, a difference in overlapping area between different first connection lines 40 and first scanning signal lines 71 caused by process deviation may be reduced, and the brightness uniformity of the plurality of sub-pixels P may be improved, thereby improving the display effect.

In some embodiments, referring to FIGS. 5, 19 and 20, the array substrate 10 further includes a second gate conductive layer GT2 and a third gate conductive layer GT3. The second gate conductive layer GT2 is provided between the first active layer ACT1 and the second active layer ACT2, and the third gate conductive layer GT3 is provided between the second active layer ACT2 and the first source-drain conductive layer SD1.

That is, the second gate conductive layer GT2 and the third gate conductive layer GT3 are disposed on opposite sides of the second active layer ACT2. The second gate conductive layer GT2 may include the first electrode plate C1 of the capacitor C.

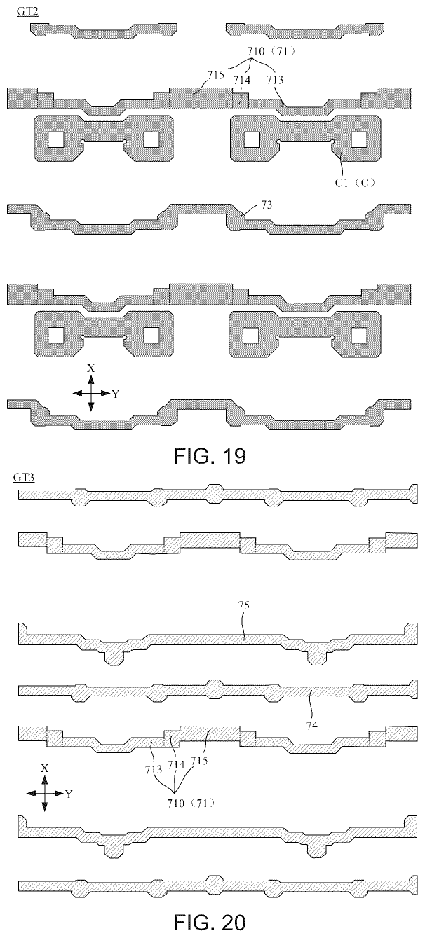

On this basis, referring to FIGS. 19 and 20, the first scanning signal lines 71 are located in the second gate conductive layer GT2 and/or the third gate conductive layer GT3. Orthographic projections of two first scanning signal lines 71 located in the second gate conductive layer GT2 and the third gate conductive layer GT3 on the reference plane may completely overlap or partially overlap, which is not specifically limited in the embodiments of the present disclosure.

For example, as shown in FIGS. 7, 18, 19 and 20, a fourth active pattern 94 overlaps with two first scanning signal lines 71, and the two first scanning signal lines 71 are located in the second gate conductive layer GT2 and the third gate conductive layer GT3 to respectively form a top gate and a bottom gate of the compensation transistor T2, thereby reducing the risk of leakage current of the compensation transistor T2.

In addition, referring to FIGS. 19 and 20, the array substrate 10 may further include a plurality of first initial signal lines 73, a plurality of second initial signal lines 74 and a plurality of third initial signal lines 75.

As shown in FIGS. 6, 19 and 20, the first initial signal line 73, the second initial signal line 74 and the third initial signal line 75 extend in the second direction Y and are respectively connected to a first initial signal terminal Vinit1, a second initial signal terminal Vinit2 and a third initial signal terminal Vinit3 of a row of pixel circuits 30. The first initial signal line 73 may be located in the second gate conductive layer GT2, and the second initial signal line 74 and the third initial signal line 75 may be located in the third gate conductive layer GT3.

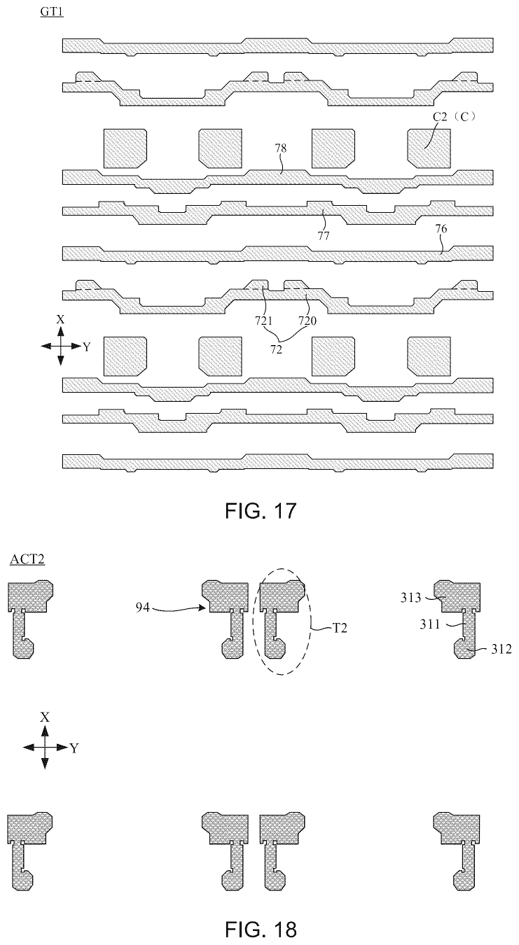

In some embodiments, referring to FIG. 17, the array substrate 10 further includes a plurality of second scanning signal lines 72. The second scanning signal lines 72 extend in the second direction Y and are each connected to a second scanning signal terminal GATE2 of a row of pixel circuits 30. Moreover, an orthographic projection of the second scanning signal line 72 on the reference plane overlaps with an orthographic projection of a channel 311 of the data writing transistor T4 on the reference plane, and overlaps with an orthographic projection of the second electrode 313 of the compensation transistor T2 on the reference plane.

On this basis, the second scanning signal line 72 includes a second scanning routing segment 720 and a plurality of widened portions 721. In the first direction X, the plurality of widened portions 721 are located on a side of the second scanning routing segment 720, and orthographic projections of the widened portions 721 on the reference plane are located within the orthographic projection of the second electrode 313 of the compensation transistor T2 on the reference plane. With such provision, the parasitic capacitance between the second scanning signal line 72 and the second electrode 313 of the compensation transistor T2 is relatively large, that is, the parasitic capacitance between the second scanning signal line 72 and the first connection line 40 is relatively large, which is beneficial to reducing a black state voltage and thus reducing the power consumption.

In some embodiments, referring to FIGS. 5 and 17, the array substrate 10 further includes a first gate conductive layer GT1. The first gate conductive layer GT1 is disposed between the first active layer ACT1 and the second gate conductive layer ACT2. On this basis, the second electrode plate C2 of the capacitor C and the second scanning signal line 72 may be located in the first gate conductive layer GT1.

In addition, referring to FIG. 17, the array substrate 10 may further include a first reset signal line 76, a second reset signal line 77 and an enabling signal line 78.

As shown in FIGS. 6 and 17, the first reset signal line 76, the second reset signal line 77 and the enabling signal line 78 extend in the second direction Y, and are respectively connected to a first reset signal terminal Reset1, a second reset signal terminal Reset2 and an enabling signal terminal EM of a row of pixel circuits 30. The first reset signal line 76, the second reset signal line 77 and the enabling signal line 78 may be located in the first gate conductive layer GT1.

It will be understood referring to FIG. 5 that, an insulating film layer can be provided between adjacent conductive film layers in the array substrate 10. For example, as shown in figures, in a direction perpendicular to the substrate 11 and toward the light-emitting device 20, the array substrate 10 includes a first active layer ACT1, a first gate conductive layer GT1, a second gate conductive layer GT2, a second active layer ACT2, a third gate conductive layer GT3, a first source-drain conductive layer SD1, a second source-drain conductive layer SD2 and a third source-drain conductive layer SD3 sequentially.

It will be noted that at least one of the first gate conductive layer GT1, the second gate conductive layer GT2, the third gate conductive layer GT3, the first source-drain conductive layer SD1, the second source-drain conductive layer SD2 and the third source-drain conductive layer SD3 may further include a transfer block, which is not specifically limited in the embodiments of the present disclosure.

On this basis, as shown in FIG. 5, in the direction perpendicular to the substrate 11 and toward the light-emitting device 20, the array substrate 10 further includes a first gate insulating layer GI1, a first interlayer insulating layer ILD1, a second gate insulating layer GI2, a third gate insulating layer GI3, a second interlayer insulating layer ILD2, a first planarization layer PLN1, a second planarization layer PLN2 and a third planarization layer PLN3.

The first gate insulating layer GI1 is located between the first active layer ACT1 and the first gate conductive layer GT1, the first interlayer insulating layer ILD1 is located between the first gate conductive layer GT1 and the second gate conductive layer GT2, the second gate insulating layer GI2 is located between the second gate conductive layer GT2 and the second active layer ACT2, the third gate insulating layer GI3 is located between the second active layer ACT2 and the third gate conductive layer GT3, the second interlayer insulating layer ILD2 is located between the third gate conductive layer GT3 and the first source-drain conductive layer SD1, the first planarization layer PLN1 is located between the first source-drain conductive layer SD1 and the second source-drain conductive layer SD2, the second planarization layer PLN2 is located between the second source-drain conductive layer SD2 and the third source-drain conductive layer SD3, and the third planarization layer PLN3 is located between the third source-drain conductive layer SD3 and the light-emitting devices 20.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. An array substrate, comprising:
pixel circuits each including a capacitor, a first reset transistor and a compensation transistor, wherein a first electrode plate of the capacitor is connected to a first voltage signal terminal, and a second electrode plate of the capacitor is connected to a first node; a first electrode of the first reset transistor is connected to a first initial signal terminal, and a second electrode of the first reset transistor is connected to a second node; and a first electrode of the compensation transistor is connected to the second node, and a second electrode of the compensation transistor is connected to the first node;
a plurality of first data lines extending in a first direction, wherein the plurality of first data lines are arranged at intervals in a second direction, the second direction intersects the first direction; a first data line is connected to a pixel circuit;
a plurality of first connection lines extending in the first direction, wherein an end of a first connection line is connected to the second electrode plate of the capacitor, and another end of the first connection line is connected to the second electrode of the compensation transistor; the first connection line is located between two adjacent first data lines, and is closer to a first data line of the two first data lines; and
a plurality of second connection lines extending in the first direction, wherein an end of a second connection line is connected to the second electrode of the first reset transistor, and another end of the second connection line is connected to the first electrode of the compensation transistor; the second connection line is located between the two adjacent first data lines; in the second direction, the second connection line is located on a side of the first connection line away from the first data line to which the first connection line is closer; and in the second direction, a maximum distance between the first connection line and the second connection line that are adjacent is less than or equal to 2.4 μm.

2. The array substrate according to claim 1, wherein the plurality of first data lines each include straight segments and bent segments that are alternately connected; the plurality of first data lines are divided into a plurality of data line groups; each data line group includes two first data lines; bent segments of two first data lines in a same data line group are disposed oppositely and bent toward directions away from each other; and
the first connection line and the second connection line are located between two first data lines that belong to different data line groups and are adjacent; and in the second direction, the first connection line is at least partially opposite to a bent segment, and opposite edges of a portion of the first connection line opposite to the bent segment and an adjacent second connection line are parallel.

3. The array substrate according to claim 2, wherein the first connection line includes a first connection pad, a first routing segment, a second routing segment and a second connection pad that are connected in sequence; the first connection pad is connected to the second electrode plate of the capacitor, and the second connection pad is connected to the second electrode of the compensation transistor;
the second connection line includes a third connection pad, a third routing segment, a fourth routing segment and a fourth connection pad that are connected in sequence; the third connection pad is connected to the first electrode of the compensation transistor, and the fourth connection pad is connected to the second electrode of the first reset transistor; and
in a direction from the first connection pad to the second connection pad, the first routing segment extends toward a direction close to the adjacent second connection line, and is located on a side of the third routing segment away from the fourth connection pad; in the second direction, the first routing segment is opposite to the third connection pad, the second routing segment is opposite to the third routing segment, and the fourth routing segment is opposite to the second connection pad; and opposite edges of the second routing segment and the third routing segment are parallel, and opposite edges of the second connection pad and the fourth routing segment are parallel.

4. The array substrate according to claim 3, wherein in the second direction, the fourth routing segment is opposite to a portion of the second connection pad, and the fourth connection pad is opposite to another portion of the second connection pad; and
orthographic projections of the second connection pad and the fourth connection pad on a reference plane are each in a shape of a polygon, and opposite edges of the second connection pad and the fourth connection pad are parallel; the reference plane is a plane determined by the first direction and the second direction.

5. The array substrate according to claim 3, wherein the second routing segment includes a first sub-segment, a second sub-segment and a third sub-segment that are connected in sequence; the first sub-segment is connected to the first routing segment, the third sub-segment is connected to the second connection pad, and the third sub-segment is farther away from the closer first data line than the first sub-segment; and
the third routing segment includes a fourth sub-segment, a fifth sub-segment and a sixth sub-segment that are connected in sequence; the fourth sub-segment is connected to the third connection pad, the sixth sub-segment is connected to the fourth routing segment, and the sixth sub-segment is farther away from the closer first data line than the fourth sub-segment; in the second direction, the first sub-segment is opposite to the fourth sub-segment, the second sub-segment is opposite to the fifth sub-segment, and the third sub-segment is opposite to the sixth sub-segment.

6. The array substrate according to claim 3, wherein opposite edges of the first routing segment and the adjacent second connection line are at least partially parallel.

7. The array substrate according to claim 1, wherein an orthographic projection of an edge of the first connection line proximate to the first data line to which the first connection line is closer on a reference plane coincides with an orthographic projection of an edge of the second electrode of the compensation transistor, connected to the first connection line, proximate to a corresponding first data line on the reference plane; and the reference plane is a plane determined by the first direction and the second direction.

8. The array substrate according to claim 1, wherein the pixel circuits each further include:
a driving transistor, wherein a control electrode of the driving transistor is connected to the first node, a first electrode of the driving transistor is connected to a third node, and a second electrode of the driving transistor is connected to the second node;
a data writing transistor, wherein a control electrode of the data writing transistor is connected to a second scanning signal terminal, a first electrode of the data writing transistor is connected to a data signal terminal, and a second electrode of the data writing transistor is connected to the third node;
a first enabling transistor, wherein a control electrode of the first enabling transistor is connected to an enabling signal terminal, a first electrode of the first enabling transistor is connected to the first voltage signal terminal, and a second electrode of the first enabling transistor is connected to the third node;
a second enabling transistor, wherein a control electrode of the second enabling transistor is connected to the enabling signal terminal, a first electrode of the second enabling transistor is connected to the second node, and a second electrode of the second enabling transistor is connected to a fourth node;
a second reset transistor, wherein a control electrode of the second reset transistor is connected to a second reset signal terminal, a first electrode of the second reset transistor is connected to a second initial signal terminal, and a second electrode of the second reset transistor is connected to the fourth node; and
a third reset transistor, wherein a control electrode of the third reset transistor is connected to the second reset signal terminal, a first electrode of the third reset transistor is connected to a third initial signal terminal, and a second electrode of the third reset transistor is connected to the third node.

9. The array substrate according to claim 8, wherein the array substrate comprises a first active layer, and the first active layer includes:
a plurality of first active patterns including a channel, a first electrode and a second electrode of the driving transistor, a channel, a first electrode and a second electrode of the data writing transistor, a channel, a first electrode and a second electrode of the first enabling transistor, a channel, a first electrode and a second electrode of the second enabling transistor, and a channel, a first electrode and a second electrode of the second reset transistor;
a plurality of second active patterns including a channel, a first electrode and a second electrode of the first reset transistor; wherein the plurality of first active patterns and the plurality of second active patterns are alternately arranged in the first direction, and a second active pattern is farther away from a corresponding first data line than a corresponding first active pattern; and
a plurality of third active patterns including a channel, a first electrode and a second electrode of the third reset transistor; wherein in the second direction, a third active pattern is located on a side of the channel of the second reset transistor proximate to the channel of the first enabling transistor.

10. The array substrate according to claim 1, further comprising:
first scanning signal lines extending in the second direction; wherein an orthographic projection of a first scanning signal line on a reference plane overlaps with an orthographic projection of a channel of the compensation transistor on the reference plane, and the reference plane is a plane determined by the first direction and the second direction, wherein
orthographic projections of the first scanning signal line and the first connection line on the reference plane overlap, and an edge of an overlapping portion is parallel to the first direction or the second direction.

11. The array substrate according to claim 10, wherein the first scanning signal line includes a plurality of first scanning routing segments connected in sequence; a first scanning routing segment includes a first scanning sub-segment and a second scanning sub-segment connected in sequence; an orthographic projection of the first scanning sub-segment on the reference plane overlaps with the orthographic projection of the first connection line on the reference plane, and an orthographic projection of the second scanning sub-segment on the reference plane overlaps with the orthographic projection of the channel of the compensation transistor on the reference plane; and
in the first direction, a width of the first scanning sub-segment is smaller than a width of the second scanning sub-segment, and an edge connecting the second scanning sub-segment and the first scanning sub-segment is parallel to an opposite edge of the first connection line.

12. The array substrate according to claim 10, wherein the first scanning signal line includes a plurality of first scanning routing segments connected in sequence; a first scanning routing segment includes a third scanning sub-segment, a fourth scanning sub-segment and a fifth scanning sub-segment connected in sequence; an orthographic projection of the fourth scanning sub-segment on the reference plane overlaps with the orthographic projection of the first connection line on the reference plane, and an orthographic projection of the fifth scanning sub-segment on the reference plane overlaps with the orthographic projection of the channel of the compensation transistor on the reference plane; and
in the first direction, a width of the third scanning sub-segment is smaller than a width of the fourth scanning sub-segment, and the width of the fourth scanning sub-segment is smaller than a width of the fifth scanning sub-segment.

13. The array substrate according to claim 12, wherein an edge connecting the fourth scanning sub-segment and the third scanning sub-segment is parallel to an opposite edge of the first connection line; and/or an edge connecting the fifth scanning sub-segment and the fourth scanning sub-segment is parallel to the opposite edge of the first connection line.

14. The array substrate according to claim 10, wherein the array substrate comprises:
a second active layer including a plurality of fourth active patterns, wherein a fourth active pattern includes a channel, a first electrode and a second electrode of the compensation transistor; and
a second gate conductive layer and a third gate conductive layer that are disposed on opposite sides of the second active layer, wherein the first scanning signal lines are located in the second gate conductive layer and/or the third gate conductive layer.

15. The array substrate according to any claim 1, wherein the pixel circuits each further include a driving transistor and a data writing transistor; a first electrode of the driving transistor is connected to a third node, and a second electrode of the driving transistor is connected to the second node; a first electrode of the data writing transistor is connected to the first data line, and a second electrode of the data writing transistor is connected to the third node;
the array substrate further comprises:
a second scanning signal line extending in the second direction, wherein an orthographic projection of the second scanning signal line on a reference plane overlaps with an orthographic projection of a channel of the data writing transistor on the reference plane, and overlaps with an orthographic projection of the second electrode of the compensation transistor on the reference plane; the reference plane is a plane determined by the first direction and the second direction, wherein
the second scanning signal line includes a second scanning routing segment and widened portions; in the first direction, the widened portions are located on a side of the second scanning routing segment, and orthographic projections of the widened portions on the reference plane are located within the orthographic projection of the second electrode of the compensation transistor on the reference plane.

16. The array substrate according to claim 1, further comprising:
a plurality of first power signal lines, wherein an orthographic projection of the first connection line on a reference plane is located within an orthographic projection of the plurality of first power signal lines on the reference plane; and the reference plane is a plane determined by the first direction and the second direction.

17. The array substrate according to claim 16, wherein the plurality of first power signal lines include:
a plurality of first power sub-lines extending in the first direction and arranged at intervals in the second direction;
a plurality of second power sub-lines extending in the first direction and arranged at intervals in the second direction; a second power sub-line is connected to a first voltage signal terminal of the pixel circuit; and
a plurality of third power sub-lines extending in the second direction and arranged at intervals in the first direction, wherein a first power sub-line is connected to a second power sub-line by a third power sub-line; part of the orthographic projection of the first connection line on the reference plane is located within an orthographic projection of the first power sub-line or the second power sub-line on the reference plane, and other part of the orthographic projection of the first connection line on the reference plane is located within an orthographic projection of the third power sub-line on the reference plane.

18. The array substrate according to claim 17, wherein the array substrate comprises:
a first source-drain conductive layer, wherein the first connection lines and the second connection lines are located in the first source-drain conductive layer;
a second source-drain conductive layer, wherein the third power sub-lines are located in the second source-drain conductive layer; and
a third source-drain conductive layer, wherein the first power sub-lines and the second power sub-lines are located in the third source-drain conductive layer.

19. A display panel, comprising:
the array substrate according to claim 1; and
light-emitting devices disposed on the array substrate.

20. A display apparatus, comprising:
the display panel according to claim 19; and
a circuit board connected to the display panel.
